(19) United States
(12) Patent Application Publication
(10) Pub. No.: US 2024/0290821 A1
(43) Pub. Date: Aug. 29, 2024

(54) METHOD OF MANUFACTURING ELECTRODE, CAPACITOR AND INTEGRATED DEVICE INCLUDING THE ELECTRODE MANUFACTURED THEREBY

(71) Applicants: Samsung Electronics Co., Ltd., Suwon-si (KR); AJOU UNIVERSITY INDUSTRY-ACADEMIC COOPERATION FOUNDATION, Suwon-si (KR)

(72) Inventors: Hyungjun KIM, Suwon-si (KR); Sang Woon LEE, Suwon-si (KR); Se Eun KIM, Gunpo-si (KR); Hye Min LEE, Suwon-si (KR); Jae Deock JEON, Suwon-si (KR); Cheheung KIM, Hwaseong-si (KR); Boeun PARK, Suwon-si (KR); Jooho LEE, Suwon-si (KR); Changsoo LEE, Suwon-si (KR)

(73) Assignees: Samsung Electronics Co., Ltd., Suwon-si (KR); AJOU UNIVERSITY INDUSTRY-ACADEMIC COOPERATION FOUNDATION, Suwon-si (KR)

(21) Appl. No.: 18/444,162

(22) Filed: Feb. 16, 2024

(30) Foreign Application Priority Data
Feb. 21, 2023 (KR) 10-2023-0023158

(51) Int. Cl. C23C 16/455

(52) U.S. Cl. CPC H01L 28/55; C23C 16/45527; H01L 28/91

(57) ABSTRACT

A method of manufacturing, by atomic layer deposition, an electrode including a perovskite type crystal structure represented by Formula 1, includes: forming a vanadium-containing precursor on a substrate; forming a vanadium-containing intermediate phase by reacting the vanadium-containing precursor with oxygen molecules; and forming a first thin film by reacting the vanadium-containing intermediate phase with water.

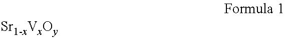

wherein, in Formula 1,
0.3≤x≤0.7, and
2.5≤y≤3.0.

### CROSS-REFERENCE TO RELATED APPLICATION

This application claims the benefit of Korean Patent Application No. 10-2023-0023158, filed on Feb. 21, 2023, in the Korean Intellectual Property Office, the disclosure of which is incorporated herein in its entirety by reference.

### BACKGROUND

### 1. Field

The present disclosure relates to a method of manufacturing an electrode, and a capacitor and an integrated device which include the electrode manufactured by the method.

### 2. Description of the Related Art

As the degree of integration of semiconductor and electronic devices increases, demand for a physical structure increasing the capacitance of capacitors disposed in a certain area, and therefore the demand for a dielectric capable of increasing capacitance, is increasing, which leads to an increase in demand for electrode materials suitable for such a dielectric.

Due to the physical structure, electrode materials need to be manufactured by atomic layer deposition. There is a demand for a method of manufacturing, by atomic layer deposition, an electrode which satisfies the physical structure, and has excellent electrode properties.

### SUMMARY

Provided are: a method of manufacturing an electrode by atomic layer deposition, the electrode being substantially free of impurities, having excellent electrical properties, and including a perovskite type crystal structure represented by Sr₁₋ₓVₓO_{y} (0.3≤x≤0.7, 2.5≤y≤3.0); and a capacitor and an integrated device, each including an electrode manufactured by the method.

Additional aspects will be set forth in part in the description which follows and, in part, will be apparent from the description, or may be learned by practice of the presented embodiments.

According to one aspect, provided is a method of manufacturing, by atomic layer deposition, an electrode including a perovskite type crystal structure represented by Formula 1 below, the method including: depositing a first vanadium (V)-containing precursor on a substrate; forming a first vanadium-containing intermediate phase by reacting the first vanadium-containing precursor with an oxygen molecule (O₂); and forming a first thin film by reacting the first vanadium-containing intermediate phase with water (H₂O):

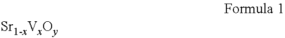

wherein, in Formula 1, 0.3≤x≤0.7, and 2.5≤y≤3.0.

According to another aspect, provided is a capacitor including: a first electrode manufactured according to the method of manufacturing an electrode and including the perovskite type crystal structure represented by Formula 1; a second electrode opposing the first electrode; and a dielectric film between the first electrode and the second electrode.

According to another aspect, provided is an integrated device including an electrode including a perovskite type crystal structure represented by Formula 1, wherein a carbon content of the electrode is 3 parts by weight or less per 100 parts by weight of the electrode, and the integrated device is a solar cell device, a secondary battery device, a transparent display device, a flash memory device, or a dynamic random-access memory (DRAM) device.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view of an integrated device according to at least one embodiment of the present disclosure;

FIG. 2 is an enlarged view of an example of a capacitor in FIG. 1;

FIG. 3 is a diagram showing a process cycle of a method of manufacturing an electrode according to at least one embodiment of the present disclosure;

FIGS. 4A and 4B are a result of X-ray photoelectron spectroscopy (XPS) analysis of an electrode manufactured according to an example of the present disclosure;

FIGS. 5A and 5B are a result of XPS analysis of an electrode manufactured according to a comparative example;

FIG. 6 is a result of XPS analysis of electrodes manufactured according to an example and comparative examples of the present disclosure;

FIG. 7 is a result of sheet resistance analysis of a first thin film manufactured according to an example and comparative examples of the present disclosure;

FIG. 8 is a result of X-ray diffraction (XRD) analysis of an electrode manufactured according to an example and a comparative example of the present disclosure; and

FIG. 9 is a drawing showing the sheet resistance and composition of an electrode manufactured according to examples of the present disclosure.

### DETAILED DESCRIPTION

Hereinafter, with reference to the appended drawings, a method of manufacturing an electrode according to at least one embodiment of the present disclosure, a capacitor manufactured thereby, and an integrated device including the electrode will be described in detail. The following is presented as an example, and the present disclosure is not limited thereby, and is only defined by the scope of the following claims.

In the following drawings, the size of each component in the drawings may be exaggerated for clarity and convenience of description. In addition, the embodiments described below are an example only, and can be subjected to various modifications. Additionally, when the terms “about” or “substantially” are used in this specification in connection with a numerical value and/or geometric terms, it is intended that the associated numerical value includes a manufacturing tolerance (e.g., ±10%) around the stated value and/or term, unless indicated otherwise. Further, regardless of whether numerical values and/or geometric terms are modified as “about” or “substantially,” it will be understood that these values should be construed as including a manufacturing or operational tolerance (e.g., ±10%) around the stated numerical values and/or geometry. When referring to “within” and/or “C to D”, this means C inclusive to D inclusive unless otherwise specified.

In the following, references to “on top of” or “above” can include being directly above by contact as well as being above by non-contact. It will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

An expression used in the singular encompasses the expression of the plural, unless it has a clearly different meaning in the context. In addition, when a part is said to “comprise” and/or be “comprising,” or to “include” and/or be “including” an element, it means that it may include additional elements, not that it excludes other elements, unless particularly stated to the contrary.

The term “combination” includes mixtures, alloys, reaction products, etc., unless particularly stated to the contrary.

Terms such as “first”, “second”, etc., may be used to describe various elements, but the elements should not be limited by these terms. These terms are used only to distinguish one element from another element.

The term “or” refers to “and/or” unless stated otherwise. References to “at least one embodiment”, “embodiments”, etc., mean that a particular element described with respect to an example is included in at least one example described herein and may or may not be present in other examples. It is also to be understood that the elements described may be combined in any suitable manner in various examples. Unless otherwise defined, all technical and scientific terms used herein have the same meaning as commonly understood by one of ordinary skill in the art to which the present disclosure belongs. While certain examples and embodiments have been described hereinafter, the appended claims and amendments are intended to include alternatives, modifications, variations, improvements, and substantial equivalents of the specific examples and embodiments.

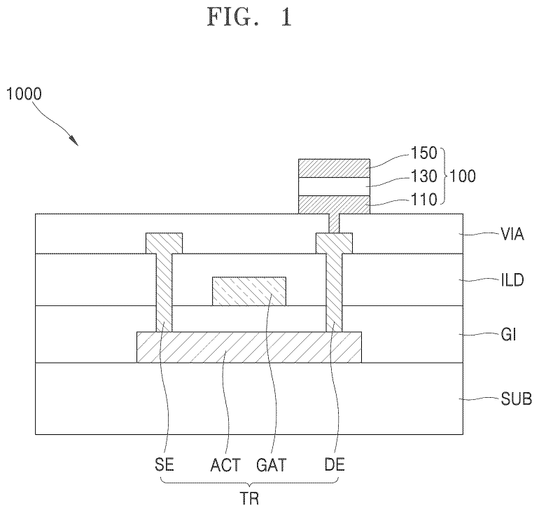

FIG. 1 is a cross-sectional view of an integrated device according to at least one embodiment of the present disclosure.

According to at least one embodiment, an integrated device 1000 includes a capacitor 100 and a transistor TR, and may be and/or be included in a solar cell device, a secondary battery device, a transparent display device, a flash memory device, a dynamic random-access memory (DRAM) device, and/or the like.

According to at least one embodiment, the solar cell device, the secondary battery device, the transparent display device, the flash memory device, and the DRAM device may include at least one electrode formed by atomic layer deposition. The electrode may include a perovskite type crystal structure represented by Formula 1 below:

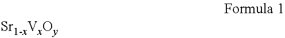

wherein, in Formula 1, Sr represents strontium, V represents vanadium, O represents oxygen, 0.3≤x≤0.7, and 2.5≤y≤3.0.

According to at least one embodiment, a carbon content of the electrode including the perovskite crystal structure and represented by Formula 1 is about 3 parts by weight (or less) per 100 parts by weight of the electrode. For example, the carbon content in the electrode may be about 1 part or less by weight per 100 parts by weight of the electrode.

According to at least one embodiment, the resistivity of the electrode included in the integrated device is about 100 mΩ·cm or less. For example, the electrode may have a resistivity of about 0.1 mΩ·cm to about 90 mΩ·cm, about 0.2 mΩ·cm to about 80 mΩ·cm, about 0.3 mΩ·cm to about 70 mΩ·cm, about 0.4 mΩ·cm to about 60 mΩ·cm, about 0.5 mΩ·cm to about 50 mΩ·cm, about 0.6 mΩ·cm to about 40 mΩ·cm, about 0.7 mΩ·cm to about 30 mΩ·cm, about 0.8 mΩ·cm to about 20 mΩ·cm, and/or about 0.9 mΩ·cm to about 10 mΩ·cm.

According to at least one embodiment, the electrode has a sheet resistance of about 50 kΩ/sq or less. For example, the sheet resistance of the electrode may be about 48 kΩ/sq or less, about 5 kΩ/sq to about 50 kΩ/sq, about 10 k Q/sq to about 48 kΩ/sq, and/or about 16 kΩ/sq to about 48 kΩ/sq.

According to at least one embodiment, the electrode has a thickness of about 0.1 nm to about 1000 nm. For example, the thickness of the electrode may be about 0.1 nm to about 800 nm, about 0.1 nm to about 500 nm, about 0.1 nm to about 300 nm, about 0.1 nm to about 100 nm, about 0.1 nm to about 80 nm, about 0.1 nm to about 50 nm, about 0.1 nm to about 30 nm, and/or about 0.1 nm to about 20 nm.

Referring to FIG. 1, the integrated device 1000 may include a substrate SUB, a transistor TR, a gate insulator GI, an interlayer dielectric ILD, a via insulator VIA, and the capacitor 100.

According to at least one embodiment, the substrate SUB may include a semiconductor, a conductor, and/or an insulator, such as SrTiO₃, Si, SiO₂, Ti, TiN, Ta, TaN, W, WN, Nb, NbN, a combination thereof, and/or the like. For example, in at least one embodiment, the substrate SUB may include a silicon on insulator (SOI) and/or may be patterned to include a conductive structure, such as a wiring pattern, via structures, redistribution structures, and/or the like (not illustrated).

According to at least one embodiment, the substrate SUB may be a plastic substrate. For example, the substrate SUB may include at least one of polyethersulphone, polyacrylate, polyetherimide, polyethylene naphthalate, polyethylene terephthalate, polyphenylene sulfide, polyarylate, polyimide, polycarbonate, cellulose acetate propionate, a combination thereof, and/or the like.

The transistor TR may include an active layer ACT, a gate electrode GAT, a source electrode SE, and a drain electrode DE. The transistor TR may be a switch transistor or a driver transistor.

The active layer ACT may be disposed on and/or in the substrate SUB. The active layer ACT may include an oxide semiconductor, an elemental semiconductor, a compound semiconductor, an organic semiconductor, a two-dimensional (2D) semiconductor, and/or the like. For example, the oxide semiconductor may include at least one oxide of at least one of indium (In), gallium (Ga), tin (Sn), zirconium (Zr), vanadium (V), hafnium (Hf), cadmium (Cd), germanium (Ge), chromium (Cr), titanium (Ti), zinc (Zn), and/or the like. For example, in at least one embodiment, the oxide semiconductor may include indium tin oxide. The elemental semiconductor may include amorphous silicon, polycrystalline silicon, germanium, etc. The active layer ACT may include a source region corresponding to the source electrode SE, a drain region corresponding to the drain electrode DE, and a channel region located between the source region and the drain region and corresponding to the gate electrode GAT. In at least one embodiment, the active layer ACT is provided on the substrate SUB; in at least one embodiment the active layer ACT may be formed from the substrate SUB. For example, the active layer ACT may be deposited, transferred, and/or formed from the substrate. In at least one embodiment, the active layer ACT may be formed by doping the substrate SUB with an impurity.

The gate insulator GI may be disposed on the active layer ACT. A gate insulator GI may cover the active layer ACT, on the substrate SUB and may include the active layer ACT from the gate electrode GAT. The gate insulator GI may include, for example, an inorganic insulating material.

The gate electrode GAT overlaps the channel region of the active layer ACT. For example, the gate electrode GAT may be disposed on the gate insulator GI, however the examples are not limited thereto. For example, the transistor TR may be a top-gate and/or a bottom-gate top contact structure. The gate electrode GAT may include a conductive material such as a metal, an alloy, a transparent conductive material, a conductive metal nitride, a conductive metal oxide, and/or the like.

In at least one embodiment, the interlayer dielectric ILD can be disposed on the gate electrode GAT. The interlayer dielectric ILD may cover the gate electrode GAT and/or may be on the gate insulator GI. The interlayer dielectric ILD may include an inorganic insulating material.

At least a portion of the source electrode SE and the drain electrode DE may be disposed on the interlayer dielectric ILD. The source electrode SE and the drain electrode DE may each be connected to the source region and the drain region of the active layer ACT through corresponding contact holes. The source electrode SE and the drain electrode DE may each include a conductive material.

The via insulator VIA may be disposed on the source electrode SE and the drain electrode DE. The via insulator VIA may cover the source electrode SE and the drain electrode DE and may be on the interlayer dielectric ILD. The via insulator VIA may include an organic insulating material.

The capacitor 100 may be disposed on the via insulator VIA. The capacitor 100 may include a first electrode 110, a dielectric thin film 130 disposed on a first electrode 110, and a second electrode 150 disposed on a dielectric thin film 130. The stacked structure of the first electrode 110, the dielectric thin film 130, and the second electrode 150 will be described further with reference to, but is not limited to the illustrated structures of FIGS. 1 and/or 2. The capacitor 100 may be a storage capacitor.

The first electrode 110 may overlap the transistor TR. The first electrode 110 may be connected to the drain electrode DE through a contact hole.

The second electrode 150 may oppose the first electrode 110. The second electrode 150 may include a conductive material. For example, the second electrode 150 may include substantially the same material as the first electrode 110.

According to at least one embodiment, the first electrode 110 and/or a second electrode 150 may include a perovskite type crystal structure represented by Formula 1.

The dielectric thin film 130 may be disposed between the first electrode 110 and the second electrode 150. The dielectric thin film 130 may include a dielectric having a dielectric constant. In at least one example, the dielectric may include a binary material such as HfₓO_{y}, ZrₓO_{y}, TiₓN_{y}, and/or TaₓN_{y} but not limited thereto. In another example, the dielectric may include a ternary oxide and/or a monoclinic oxide having a perovskite type crystal structure. Examples of the ternary oxide include at least one of KTaO₃, CaTiO₃, SrTiO₃, SrZrO₃, SrHfO₃, BaTiO₃, BaHfO₃, BaZrO₃, Sr₂Nb₃O₁₀, Sr₂Nb₃O_{9.5}, Ca₂Nb₃O₁₀, Ca₂Nb₃O_{9.5}, Ba₂Nb₃O₁₀, Ba₂Nb₃O_{9.5}, Sr₂Ta₃O₁₀, Sr₂Ta₃O_{9.5}, Ca₂Ta₃O₁₀, Ca₂Ta₃O_{9.5}, Ba₂Ta₃O₁₀, Ba₂Ta₃O_{9.5}, a combination thereof, and/or the like, but is not limited thereto. Examples of the ternary oxide may include, but are not limited to, (Ca,Sr)TiO₃, (Ba,Sr)TiO₃, (Ba,Zr)TiO₃, and/or a combination thereof, which are doped forms of the ternary oxide.

As the integrated device 1000 is miniaturized, the area on which the capacitor 100 is disposed decreases, and according to high performance of the integrated device 1000, high capacitance of the capacitor 100 may be required.

The capacitance of the capacitor 100 can be calculated by Equation 1 below:

$$C = k \times A / d \qquad Equation 1$$

wherein, in Equation 1, C is the capacitance of the capacitor, k is the dielectric constant of the dielectric, A is an area of the first or second electrode (for example, the area where the first and second electrode overlap), d is the thickness between the first and second electrode (for example, the thickness of the dielectric).

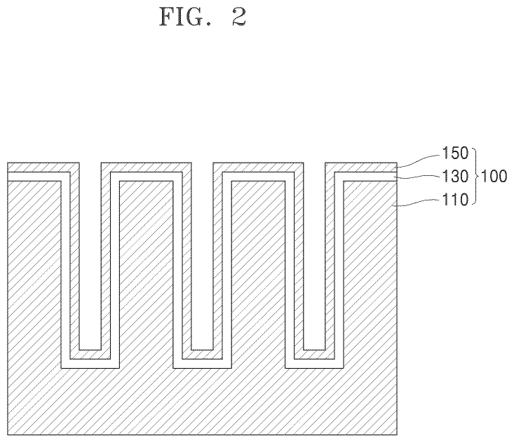

FIG. 2 is an enlarged view of an example of the capacitor in FIG. 1.

To increase the capacitance of the capacitor 100, the structure of the capacitor 100, such as shown in FIG. 2, may have a relatively high A and a relatively low d. FIG. 2 shows one example of the physical structure of a capacitor 100 for increasing capacitance, but the structure of the capacitor 100 is not limited thereto.

Referring to FIG. 2, in order to miniaturize the capacitor 100 while increasing the area of an electrode (for example, A in Equation 1), the first electrode 110 may have a protruding shape in the thickness direction. Accordingly, the dielectric thin film 130 may be formed along the profile of the first electrode 110. In addition, the dielectric thin film 130 may be formed relatively thin to reduce the thickness between the two electrodes (for example, d in Equation 1). The second electrode 150 may be formed along the profile of a dielectric thin film 130. Atomic layer deposition may be essentially required to the manufacture of the physical structure.

In addition to improving the physical structure of the capacitor 100 to increase the capacitance of the capacitor 100, a dielectric material having a high dielectric constant (for example, k of Equation 1) may be required. The dielectric constant of a ternary oxide dielectric, including a perovskite type crystal structure, may be greater than the dielectric constant of a binary oxide dielectric. However, the perovskite type crystal structure is often less stable than the structure of the binary oxide dielectrics. Accordingly, in order to support the stability of the perovskite type crystal structure, the first electrode 110 and the second electrode 150 of the capacitor 100 have a crystalline phase suitable for a ternary oxide dielectric including the perovskite type crystal structure may be required.

The present disclosure may provide a method of manufacturing, by atomic layer deposition, an electrode including a perovskite type crystal structure represented by Formula 1.

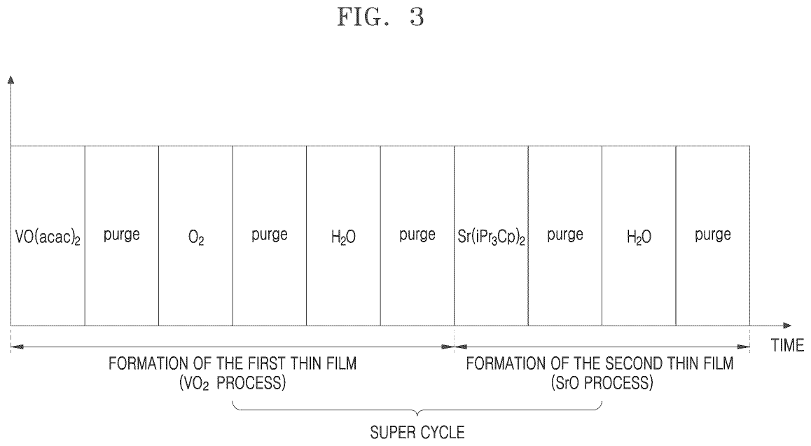

FIG. 3 is a diagram showing a process cycle of a method of manufacturing an electrode according to at least one embodiment of the present disclosure.

Referring to FIG. 3, the method of manufacturing, by atomic layer deposition (ALD), an electrode including a perovskite type crystal structure represented by Formula 1, may include one super cycle and/or multiple repeated super cycles.

The super cycle may include a process of forming a first thin film containing vanadium (V) (which, for example, may be referred to as a VO₂ process) and a process of forming a second thin film containing strontium (Sr) (which, for example, may be referred to as a SrO process). In FIG. 3, the super cycle of the method of manufacturing an electrode is shown as including forming one first thin film and forming one second thin film, but the super cycle of the method of manufacturing an electrode according to the present disclosure may include i) forming two first thin films and forming one second thin film, ii) forming one first thin film and forming two second thin films, and/or iii) forming three first thin films and forming one second thin film, or in addition may include iv) forming two first thin films and forming two second thin films, and so on, and it would be commonly understood by one of ordinary skill in the art that the super cycle may include various combinations. For example, the super cycle included in the method of manufacturing an electrode may include forming m (1≤m) first thin films and n (1≤n) second thin films in any order.

According to one aspect, the method of manufacturing, by atomic layer deposition, an electrode including a perovskite type crystal structure represented by Formula 1, may include: depositing a first vanadium-containing precursor on a substrate; forming a first vanadium-containing intermediate phase by reacting the first vanadium-containing precursor with an oxygen molecule (O₂); and forming a first thin film by reacting the first vanadium-containing intermediate phase with water (H₂O).

That is, in at least one embodiment, the method of manufacturing an electrode includes reacting the first vanadium-containing intermediate phase with water after reacting an oxygen molecule with the first vanadium-containing precursor, which is clearly distinct from reacting with an oxygen molecule after reacting water with the first vanadium-containing precursor and, which as discussed below, produces different properties.

According to at least one embodiment, the method of manufacturing, by atomic layer deposition, an electrode including a perovskite type crystal structure represented by Formula 1, may include: depositing a first vanadium-containing precursor on a substrate; purging to discharge residual reactants; forming a first vanadium-containing intermediate phase by reacting the first vanadium-containing precursor with an oxygen molecule (O₂); purging to discharge residual reactants; forming a first thin film by reacting the first vanadium-containing intermediate phase with water (H₂O); purging to discharge residual reactants; depositing a strontium-containing precursor on the first thin film; purging to discharge residual reactants; forming a second thin film by reacting the strontium-containing precursor with an oxidizing agent; and purging to discharge residual reactants.

However, one or more processes of purging to discharge residual reactants may be omitted.

According to another embodiment, the method of manufacturing, by atomic layer deposition, an electrode including a perovskite type crystal structure represented by Formula 1, may include: depositing a first vanadium-containing precursor on a substrate; purging to discharge residual reactants; forming a first vanadium-containing intermediate phase by reacting the first vanadium-containing precursor with an oxygen molecule (O₂); purging to discharge residual reactants; forming a first thin film by reacting the first vanadium-containing intermediate phase with water (H₂O); purging to discharge residual reactants; depositing a second vanadium-containing precursor on the first thin film; purging to discharge residual reactants; forming a second vanadium-containing intermediate phase by reacting the second vanadium-containing precursor with an oxygen molecule (O₂); purging to discharge residual reactants; forming a third thin film by reacting the second vanadium-containing intermediate phase with water (H₂O); purging to discharge residual reactants; depositing a strontium-containing precursor on the third thin film; purging to discharge residual reactants; forming a second thin film by reacting the strontium-containing precursor with an oxidizing agent; and purging to discharge residual reactants.

However, one or more processes of purging to discharge residual reactants may be omitted.

According to at least one embodiment, the oxidizing agent may be H₂O₂, H₂O, O₂, O₃ or any combination thereof. For example, the oxidizing agent may be H₂O.

According to at least one embodiment, the first vanadium-containing precursor may be free of chlorine (Cl). For example, the first vanadium-containing precursor may be vanadyl acetylacetonate (hereinafter referred to as VO(acac)₂).

According to at least one embodiment, the strontium-containing precursor may not contain an oxygen atom (O). For example, the strontium-containing precursor may not be Sr(tmhd)₂. The strontium-containing precursor may include a five-membered carbon ring. For example, the strontium-containing precursor may be Sr(iPr₃Cp)₂ (Bis(1,2,4-tri-isopropylcyclopentadienyl)strontium).

According to at least one embodiment, forming a first vanadium-containing precursor on the substrate is performed at about 350° C. or higher. Specifically, the method of manufacturing, by atomic layer deposition, an electrode including a perovskite type crystal structure represented by Formula 1, may be performed at about 350° C. or higher. That is, forming the first thin film containing vanadium and forming the second thin film containing strontium may be performed at about 350° C. or higher.

For example, the method of manufacturing, by atomic layer deposition, an electrode including a perovskite type crystal structure represented by Formula 1, may be performed at about 350° C. to about 500° C., preferably at about 360° C. to about 450° C., and more preferably at about 370° C. to about 425° C.

According to at least one embodiment, the oxidation number of vanadium in the first thin film may be +4. That is, the first thin film may contain substantially V⁴⁺ and/or substantially no V⁵⁺.

According to at least one embodiment, in Formula 1, y may be 3.

According to at least one embodiment, in Formula 1, x may be 0.4 to 0.6, preferably 0.45 to 0.55, and more preferably 0.5.

According to at least one embodiment, a carbon content of the electrode manufactured according to the method of manufacturing, by atomic layer deposition, an electrode including a perovskite type crystal structure represented by Formula 1, may be about 3 parts or less by weight per 100 parts by weight of the electrode, For example, the carbon content of the electrode may be about 1 part or less by weight per 100 parts by weight of the electrode.

According to at least one embodiment, an electrode manufactured according to the method of manufacturing, by atomic layer deposition, an electrode including a perovskite type crystal structure represented by Formula 1, has a resistivity of about 100 mΩ·cm or less. For example, the resistivity of the electrode may be about 0.1 mΩ·cm to about 90 mΩ·cm, about 0.2 mΩ·cm to about 80 mΩ·cm, about 0.3 mΩ·cm to about 70 mΩ·cm, about 0.4 mΩ·cm to about 60 mΩ·cm, about 0.5 mΩ·cm to about 50 mΩ·cm, about 0.6 mΩ·cm to about 40 mΩ·cm, about 0.7 mΩ·cm to about 30 mΩ·cm, about 0.8 mΩ·cm to about 20 mΩ·cm, or about 0.9 mΩ·cm to about 10 mΩ·cm.

According to at least one embodiment, an electrode manufactured according to the method of manufacturing, by atomic layer deposition, an electrode including a perovskite type crystal structure represented by Formula 1, has a sheet resistance of about 50 kΩ/sq or less. For example, the sheet resistance of the electrode may be about 48 kΩ/sq or less, about 5 kΩ/sq to about 50 kΩ/sq, preferably about 10 k Q/sq to about 48 kΩ/sq, and even more preferably about 16 k Q/sq to about 48 kΩ/sq.

According to at least one embodiment, the electrode may have a thickness of about 0.1 nm to about 1000 nm. For example, the thickness of the electrode may be about 0.1 nm to about 800 nm, about 0.1 nm to about 500 nm, about 0.1 nm to about 300 nm, about 0.1 nm to about 100 nm, about 0.1 nm to about 80 nm, about 0.1 nm to about 50 nm, about 0.1 nm to about 30 nm, or about 0.1 nm to about 20 nm.

An electrode manufactured according to the method of manufacturing an electrode including the perovskite type crystal structure represented by Formula 1, has a perovskite type crystalline phase, and thus may have excellent compatibility with dielectrics including ternary oxides having a perovskite type crystal structure.

An electrode manufactured according to the method of manufacturing an electrode as described above has a thickness of about 0.1 nm to about 1000 nm, and has the physical structure shown in FIG. 2 as an example, and therefore may be manufactured by atomic layer deposition. That is, the present disclosure is clearly distinct from an electrode manufactured by conventional physical vapor deposition (PVD) and/or conventional chemical vapor deposition (CVD).

An electrode manufactured according to the method of manufacturing an electrode as described above is substantially free of impurities (elements other than strontium, vanadium, and oxygen, such as carbon and chlorine), including about 3 wt % or less of impurities, and has a resistivity of about 100 mΩ·cm or less, and thus has excellent electrical properties.

Hereinafter, a method of manufacturing an electrode in accordance with at least one embodiment of the present disclosure will be described in more detail through examples, however the present disclosure is not limited to the following examples. In the following examples or comparative examples, when the expression “substance ‘B’ is used instead of substance ‘A″’ is used, the amount of ‘B’ and the amount of ‘A’ are the same on a molar basis.

### Example 1 (Si/VO(acac)₂/O₂/H₂O/Sr(iPr₃Cp)₂/H₂O)

An electrode including a first thin film, a second thin film, and a perovskite type crystal structure denoted by SrVO₃ was manufactured by a super cycle including processes i) through v) below, repeated at least once.
i) Vanadyl acetylacetonate (VO(acac)₂) was deposited on Si-containing substrates by atomic layer deposition. In a purging step, the residual reactants were discharged.
ii) VO(acac)₂ and O₂ were reacted to form a first vanadium-containing intermediate phase. In a purging step, the residual reactants were discharged.
iii) The first vanadium-containing intermediate phase was reacted with H₂O to form a first thin film including VO₂. In a purging step, the residual reactants were discharged.
iv) Sr(iPr₃Cp)₂ was deposited on the first thin film by atomic layer deposition. In a purging step, the residual reactants were discharged.
v) Sr(iPr₃Cp)₂ and H₂O were reacted to form a second thin film. In a purging step, the residual reactants were discharged.

### Example 2 (SiO₂/VO(acac)₂/O₂/H₂O/Sr(iPr₃Cp)₂/H₂O)

An electrode including a first thin film, a second thin film, and a perovskite type crystal structure of SrVO₃ was manufactured in the same manner as in Example 1, except that a substrate including SiO₂ was used instead of a substrate including Si.

### Example 3 (Si/VO(acac)₂/O₂/H₂O/VO(acac)₂/O₂/H₂O/Sr(iPr₃Cp)₂/H₂O)

An electrode including a first thin film, a second thin film, a third thin film, and a perovskite type crystal structure denoted by SrVO₃ was manufactured in the same manner as in Example 1, except that the super cycle of Example 1 further included processes 1) through 3) below, between iii) and iv) of Example 1.
1) VO(acac)₂ was deposited on a first thin film containing VO₂ by atomic layer deposition. In a purging step, the residual reactants were discharged.
2) VO(acac)₂ and O₂ were reacted to form a second vanadium-containing intermediate phase. In a purging step, the residual reactants were discharged.
3) The second vanadium-containing intermediate phase was reacted with H₂O to form a third thin film containing VO₂. In a purging step, the residual reactants were discharged.

### Example 4 (Si/VO(acac)₂/O₂/H₂O/VO(acac)₂/O₂/H₂O/VO(acac)₂/O₂/H₂O/Sr(iPr₃Cp)₂/H₂O)

An electrode including a first thin film, a second thin film, a third thin film, a fourth thin film, and including a perovskite type crystal structure denoted by SrVO₃ was manufactured in the same manner as in Example 1, except that the super cycle of Example 1 further included processes 1) through 6) below, between iii) and iv) of Example 1.
1) VO(acac)₂ was deposited on a first thin film containing VO₂ by atomic layer deposition. In a purging step, the residual reactants were discharged.
2) VO(acac)₂ and O₂ were reacted to form a second vanadium-containing intermediate phase. In a purging step, the residual reactants were discharged.
3) The second vanadium-containing intermediate phase was reacted with H₂O to form a third thin film containing VO₂. In a purging step, the residual reactants were discharged.
4) VO(acac)₂ was deposited on a third thin film containing VO₂ by atomic layer deposition. In a purging step, the residual reactants were discharged.
5) VO(acac)₂ and O₂ were reacted to form a third vanadium-containing intermediate phase. In a purging step, the residual reactants were discharged.
6) The third vanadium-containing intermediate phase was reacted with H₂O to form a fourth thin film containing VO₂. In a purging step, the residual reactants were discharged.

### Comparative Example 1 (Si/VCl₄/O₂/H₂O/Sr(iPr₃Cp)₂/H₂O)

An electrode was manufactured in the same manner as in Example 1, except that VCl₄ was used instead of VO(acac)₂ as the first vanadium-containing precursor.

### Comparative Example 2 (Si/VO(acac)₂/H₂O/Sr(iPr₃Cp)₂/H₂O)

An electrode was manufactured in the same manner as in Example 1, except that process ii-1) below was performed instead of ii) and iii) in Example 1.

ii-1) The VO(acac)₂ and H₂O were reacted to form a thin film. In a purging step, the residual reactants were discharged.

### Comparative Example 3 (Si/VO(acac)₂/O₂/Sr(iPr₃Cp)₂/H₂O)

An electrode was manufactured in the same manner as in Example 1, except that process iii-1) below was performed instead of ii) and iii) in Example 1.

iii-1) the VO(acac)₂ and O₂ were reacted to form a thin film. In a purging step, the residual reactants were discharged.

### Comparative Example 4 (Si/VO(acac)₂/H₂O/O₂/Sr(iPr₃Cp)₂/H₂O)

An electrode was manufactured in the same manner as in Example 1, except that processes ii-2) and iii-2) were, respectively, performed instead of ii) and iii) in Example 1.

ii-2) VO(acac)₂ and H₂O were reacted to form a vanadium-containing intermediate phase. In a purging step, the residual reactants were discharged.

iii-2) By forming O₂ on the vanadium-containing intermediate phase by atomic layer deposition, the vanadium-containing intermediate phase was reacted with O₂ to form a thin film. In a purging step, the residual reactants were discharged.

### Comparative Example 5 (SiO₂/VO(acac)₂/O₂/Sr(iPr₃Cp)₂/H₂O)

An electrode was manufactured in the same manner as in Comparative Example 3, except that a substrate containing SiO₂ was used instead of the substrate containing Si in Comparative Example 3.

### Evaluation Example 1 (Vanadium-Containing Precursor Evaluation)

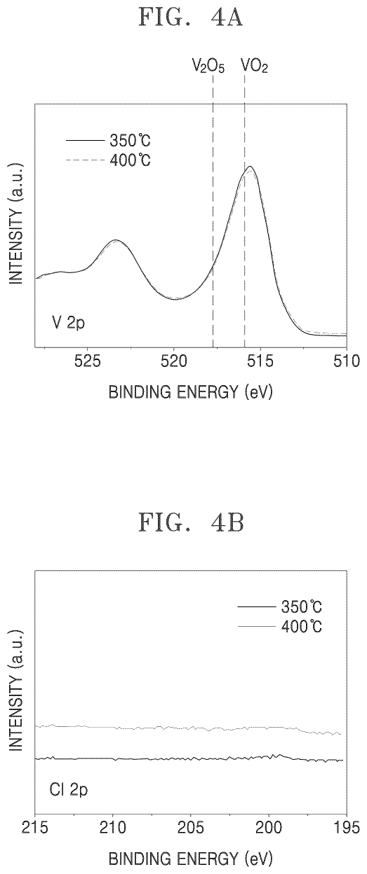

FIG. 4 (A) is a result of an X-ray photoelectron spectroscopy (XPS) analysis of a vanadium-containing thin film (the first thin film) of the electrode according to Example 1, and FIG. 4 (B) is a result of XPS analysis of the electrode according to Example 1. In FIG. 4 (A) and (B), the solid line indicates the result of performing the method of manufacturing the electrode of Example 1 at 350° C., and the dashed line indicates the result of performing the method of manufacturing the electrode of Example 1 at 400° C.

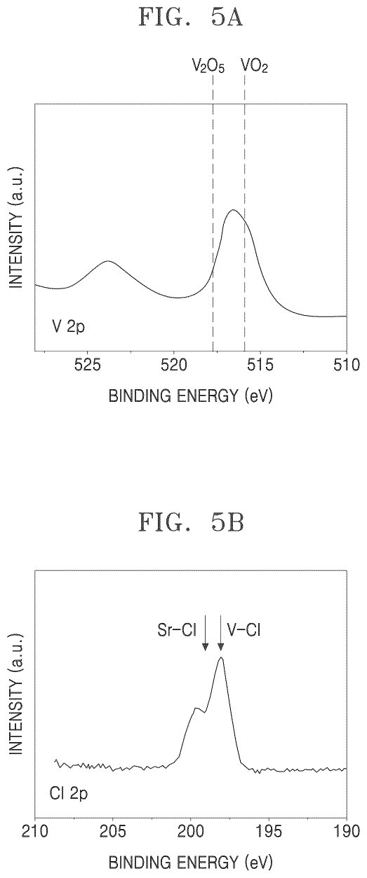

FIG. 5(A) is a result of XPS analysis of a vanadium-containing thin film of the electrode according to Comparative Example 1, and FIG. 5(B) is a result of XPS analysis of the electrode according to Comparative Example 1.

Referring to FIG. 4 (A), it can be seen that the vanadium-containing thin film according to Example 1 has a relatively narrow peak at a binding energy of about 516 eV and therefore contains VO₂. Referring to FIG. 4 (B), it can be seen that the electrode according to Example 1 does not have a peak at about 197 eV to about 200 eV, and thus substantially does not contain Cl as an impurity of SrVO₃.

However, referring to FIG. 5 (A), it can be seen that the vanadium-containing thin film according to Comparative Example 1 contains VO₂ as well as V₂O₅ as a result of the relatively increased content of V₂O₅ observed at about 518 eV. That is, the vanadium-containing thin film according to Comparative Example 1 contains a mixture of V⁴⁺ of oxide number 4 and V⁵⁺ of oxide number 5. In addition, referring to FIG. 5 (B), it can be seen that the electrode according to Example 1 has peaks at about 197 eV (for example, V—Cl binding energy) and about 200 eV (for example, Sr—Cl binding energy), indicating that it contains Cl as an impurity in SrVO₃. This is due to HCl generated during the reaction of VCl₄ with H₂O. HCl can cause adsorption problems between VO₂ and SrO, which can hinder the formation of SrVO₃.

Therefore, VO(acac)₂ may be appropriate as a vanadium-containing precursor for the formation of SrVO₃.

### Evaluation Example 2 (Vanadium-Containing Precursors Oxidizer Evaluation)

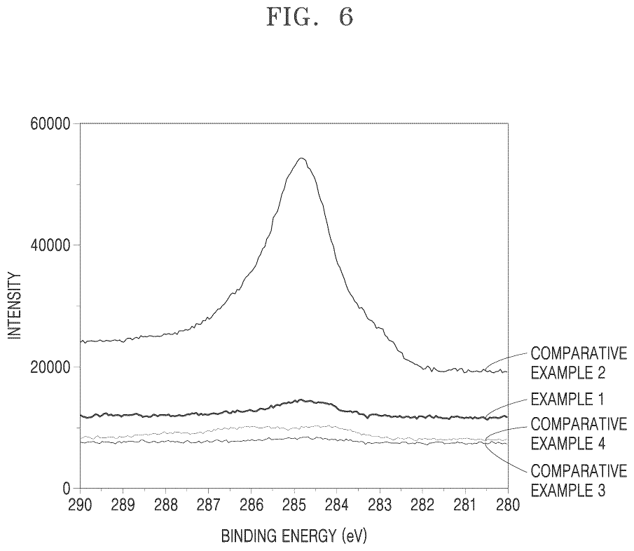

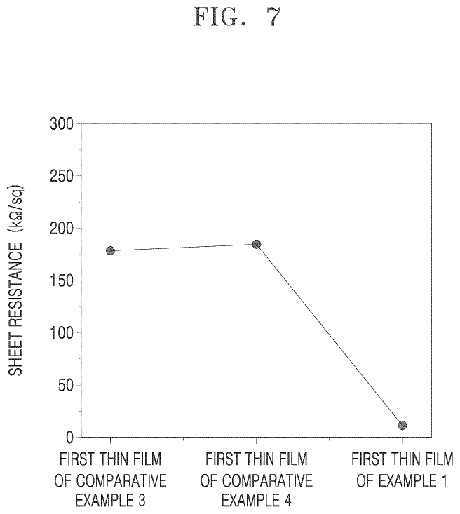

FIG. 6 is a result of X-ray photoelectron spectroscopy (XPS) analysis of a vanadium-containing thin film of each of the electrodes according to Example 1 and Comparative Examples 2 through 4. FIG. 7 is a result of sheet resistance analysis of a vanadium-containing thin film (first film) of each of the electrodes according to Example 1 and Comparative Examples 2 to 4.

The binding energy of carbon-hydrogen bonds (C—H) and carbon-carbon bonds (C—C) is about 285 eV. Therefore, the carbon content per 100 parts by weight of the vanadium-containing thin film can be determined by Measure 1 in Table 1 below.

TABLE 1

| | |
|---|---|
| Measure 1 | The results of X-ray photoelectron spectroscopy (XPS) |
| | analysis of the vanadium-containing thin film determined |
| | the carbon content (wt %) in the vanadium-containing thin |
| | films as a ratio of the area at about 284 eV to about 286 eV |
| | to the total area of the graph. |

Referring to FIG. 6, it can be seen that the vanadium-containing thin film according to Comparative Example 2 (Si/VO(acac)₂/H₂O/Sr(iPr₃Cp)₂/H₂O) using only H₂O as an oxidizer of the vanadium-containing precursor has a relatively high and broad peak at about 285 eV, indicating that it contains a relatively high amount of carbon as an impurity. Therefore, the electrode manufactured according to Comparative Example 2 using only H₂O as an oxidant of the vanadium-containing precursor may contain a relatively low purity of SrVO₃.

Referring to FIG. 7, the sheet resistance of the vanadium-containing thin films according to Comparative Example 3 (Si/VO(acac)₂/O₂/Sr(iPr₃Cp)₂/H₂O) using only O₂ as an oxidizing agent for the vanadium-containing precursor and Comparative Example 4 (Si/VO(acac)₂/H₂O/O₂/Sr(iPr₃Cp)₂/H₂O) using O₂ after sequentially using H₂O as the oxidizing agent for the vanadium-containing precursor, is about 170 kΩ/sq, and thus can be seen to have relatively high sheet resistance. However, the vanadium-containing thin film (first thin film) according to Example 1 (Si/VO(acac)₂/O₂/H₂O/Sr(iPr₃Cp)₂/H₂O) using H₂O after sequentially using O₂ as an oxidizing agent for the vanadium-containing precursor has a relatively low sheet resistance of about 50 kΩ/sq or less, and thus an electrode manufactured according to an example of the present disclosure may have excellent electrical properties.

### Evaluation Example 3 (Crystalline Evaluation)

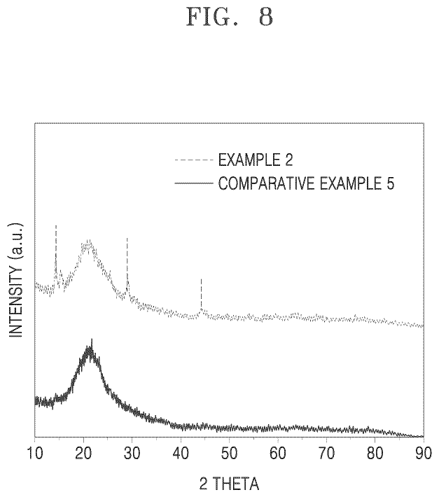

FIG. 8 is a result of X-ray diffraction (XRD) analysis of each of the vanadium-containing thin films according to Example 2 and Comparative Example 5.

The crystalline phase of VO₂ (B) may have peaks at about 15°, about 30°, and about 45°.

Referring to FIG. 8, it can be seen that the vanadium-containing thin film according to Example 2 has a peak in the range of about 15°, 2θ°, and 45°, while the vanadium-containing thin film according to Comparative Example 5 does not have a peak in the range of 15 or 45°. Therefore, the vanadium-containing thin film according to Example 2 (SiO₂/VO(acac)₂/O₂/H₂O/Sr(iPr₃Cp)₂/H₂O) has a crystalline phase of VO₂(B) on a SiO₂ substrate, while the vanadium-containing thin film according to Comparative Example 5 (SiO₂/VO(acac)₂/O₂/Sr(iPr₃Cp)₂/H₂O) may not have a crystalline phase or may be less crystalline on a SiO₂ substrate.

Therefore, electrodes manufactured according to an example of the present disclosure may have excellent compatibility with dielectrics having a relatively high dielectric constant and a perovskite type crystal structure.

### Evaluation Example 4 (Cycle Rate Evaluation)

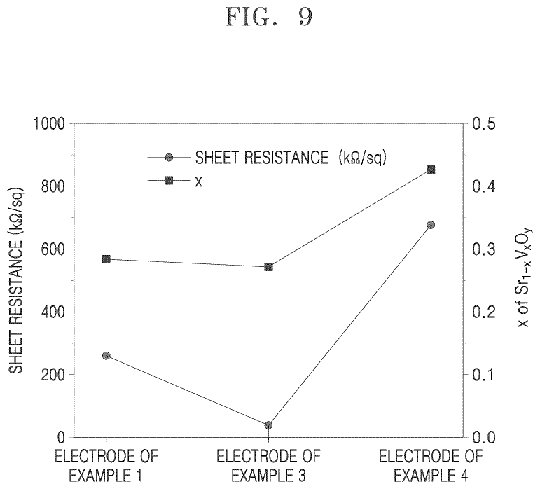

FIG. 9 is a diagram showing the sheet resistance and composition for each of the electrodes according to Example 1, Example 3, and Example 4. Specifically, the left axis of FIG. 9 represents the sheet resistance of the electrode, and the right axis of FIG. 9 represents the value of x in Formula 1:

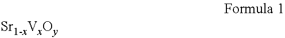

In Example 1 (Si/VO(acac)₂/O₂/H₂O/Sr(iPr₃Cp)₂/H₂O), one super cycle includes one VO₂ process and one SrO process. In Example 3 (Si/VO(acac)₂/O₂/H₂O/VO(acac)₂/O₂/H₂O/Sr(iPr₃Cp)₂/H₂O), one super cycle includes two VO₂ processes and one SrO process. In Example 4 (Si/VO(acac)₂/O₂/H₂O/VO(acac)₂/O₂/H₂O/VO(acac)₂/O₂/H₂O/Sr(iPr₃Cp)₂/H₂O), one super cycle includes three VO₂ processes and one SrO process.

Referring to FIG. 9, it can be seen that the sheet resistance of the electrode manufactured according to the present disclosure and the x value in Formula 1 can be adjusted by changing the number of VO₂ processes and SrO processes included in the super cycle. For example, it would be commonly understood by one of ordinary skill in the art that the number of VO₂ processes and SrO processes can be changed such that x in Formula 1 is 0.5 and the sheet resistance of the electrode is about 50 kΩ/sq or less. In addition, by adjusting the sheet resistance of the electrode, the number of VO₂ processes and SrO processes can be changed such that the resistivity of the electrode is about 10 mΩ·cm or less.

The method of manufacturing the electrode can provide an electrode that has excellent compatibility with a dielectric including a ternary oxide having a perovskite type crystal structure, is substantially free of impurities, and has excellent electrical properties.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A method of manufacturing, by atomic layer deposition, an electrode including a perovskite type crystal structure represented by Formula 1 below, the method comprising:
depositing a first vanadium (V)-containing precursor on a substrate;
forming a first vanadium-containing intermediate phase by reacting the first vanadium-containing precursor with an oxygen molecule (O₂); and
forming a first thin film by reacting the first vanadium-containing intermediate phase with water (H₂O), 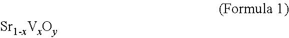
wherein, in Formula 1,
0.3≤x≤0.7, and
2.5≤y≤3.0.

2. The method of claim 1, further comprising:
depositing a strontium (Sr)-containing precursor on the first thin film; and
forming a second thin film by reacting the strontium-containing precursor with an oxidizing agent.

3. The method of claim 2, wherein the oxidizing agent is at least one of H₂O₂, H₂O, O₂, or O₃.

4. The method of claim 2, further comprising, between the forming of the first thin film and the forming of the second thin film:
depositing a second vanadium-containing precursor on the first thin film;
forming a second vanadium-containing intermediate phase by reacting the second vanadium-containing precursor with an oxygen molecule (O₂); and
forming a third thin film by reacting the second vanadium-containing intermediate phase with water (H₂O).

5. The method of claim 1, wherein the first vanadium-containing precursor is free of chlorine (Cl).

6. The method of claim 1, wherein the first vanadium-containing precursor is vanadyl acetylacetonate.

7. The method of claim 1, wherein the depositing of the first vanadium-containing precursor on the substrate is performed at about 350° C. or higher.

8. The method of claim 1, wherein the first thin film contains substantially no V⁵⁺.

9. The method of claim 2, wherein the strontium-containing precursor is free of oxygen atoms (O).

10. The method of claim 2, wherein the strontium-containing precursor comprises a five-membered carbon ring.

11. The method of claim 2, wherein the strontium-containing precursor is Sr(iPr₃Cp)₂ (Bis(1,2,4-tri-isopropylcyclopentadienyl)strontium).

12. The method of claim 1, wherein the substrate comprises at least one of SrTiO₃, Si, SiO₂, Ti, TiN, Ta, TaN, W, WN, Nb, or NbN.

13. The method of claim 1, wherein y, in Formula 1, is 3.

14. The method of claim 1, wherein a carbon content of the electrode is about 3 or less parts by weight per 100 parts by weight of the electrode.

15. The method of claim 1, wherein the electrode has a resistivity of about 100 mΩ·cm or less.

16. The method of claim 1, wherein the electrode has a thickness of about 0.1 nm to about 1000 nm.

17. A capacitor comprising:
a first electrode manufactured according to the method of claim 1 and including the perovskite type crystal structure represented by Formula 1;
a second electrode opposing the first electrode; and
a dielectric thin film between the first electrode and the second electrode.

18. An integrated device comprising:
an electrode comprising a perovskite type crystal structure represented by Formula 1 below, wherein
a carbon content of the electrode is about 3 or less parts by weight per 100 parts by weight of the electrode, and
the integrated device is a solar cell device, a secondary battery device, a transparent display device, a flash memory device, or a dynamic random-access memory (DRAM) device: 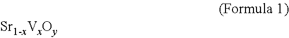
wherein, in Formula 1,
0.3≤x≤0.7, and
2.5≤y≤3.0.

19. The integrated device of claim 18, wherein the electrode is formed by atomic layer deposition.

20. The integrated device of claim 18, wherein the electrode has a resistivity of about 100 mΩ·cm or less.
